(19) United States
(12) Patent Application Publication
(10) Pub. No.: US 2009/0034198 A1
(43) Pub. Date: Feb. 5, 2009

(54) APPARATUS AND METHOD FOR ATTACHING HEATSINKS

(75) Inventors: John L. Colbert, Byron, MN (US); John S. Corbin, Jr., Austin, TX (US); Jason R. Eagle, Kasson, MN (US); Arvind K. Sinha, Rochester, MN (US); Christopher L. Tuma, Mantorville, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/831,135

(22) Filed: Jul. 31, 2007

(51) Int. Cl. H05K 7/20

(52) U.S. Cl. 361/704

(57) ABSTRACT

An apparatus for attaching a heatsink to an electronic module mounted on a circuit card assembly includes a load frame; a load arm having a first end being pivotally coupled to one end of the load frame and a second end configured to receive at least a portion of a load screw therethrough; a spring plate disposed at an opposite end of the one end of the load frame, and configured to threadedly receive the load screw, opposite ends of the spring plate being retained while an intermediate portion threadedly receiving the at least a portion of the load screw is allowed to bow upwards toward a bottom of the opposite end of the load arm; and a heatsink disposed on the module. An intermediate portion of the load arm aligned with a center region of the module biases the heatsink toward the module when the load screw is threadedly engaged with the spring plate.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to heatsinks, and particularly to an apparatus and method for attaching the heatsinks to an electronic module, such as an organic ball or column grid array, but also modules that are socketed to a board, and more specifically, that are land grid array socketed to the board.

2. Description of Background

Conventionally, heatsink attachment is accomplished by (1) attaching the heatsink directly to the module via a thermal adhesive, spring clip, etc.; or (2) elastically attaching the heatsink to the card via a spring clip, or the like, while pre-loading the heatsink against the module. When an electronic module, such as a microprocessor, is surface mounted to a circuit board via solder balls, solder columns, or the like, the conventional methods for attaching a large heatsink can be defective. More specifically, the conventional methods can be inadequate for resisting shock and vibration, such as those encountered during handling and shipping of the computer system.

In a heatsink on module application, it has been observed that loading at the corners of the heatsink induces a bow in the base of the heatsink. This is due to the loads being applied at some distance from the opposing surface-resulting in a bending of the heatsink base. This bending has several negative impacts that may be critical. The bending of the base affects the planarity between the module and the heatsink pedestal. If the corners are loaded, the heatsink typically bends concave down, which increases the gap between the center of the module and the heatsink. This also results in exposing the corners of the module to higher pressure.

Typically, there are four loading mechanisms per heatsink (one per corner), which may typically be “cross-tightened” to bring the total load up slowly. This has a negative impact in that the corner loads are increased incrementally, yet a concentration of force at each corner cannot be avoided as force is actuated-regardless of how small the increment is. This concentration of incrementally applied force requires special consideration to ensure that it is not sufficiently high to crack the corners of the module.

One of the ways this incremental loading problem has been overcome, is by centrally applying a load to the top of the heatsink using a fixture, then actuating the corner loading mechanisms. After the corner load mechanisms are tightened to their stops, the fixture is then removed. This method has several drawbacks. The fixture load has been applied to the center of the heatsink, which results in a relatively flat profile at the base of the heatsink. This is due to the applied load being directly over the opposing force (module). If the fixture applies the load to the center of the heatsink, the thermal interface material (TIM) will be compressed to a profile that is representative of a centrally loaded system.

However, when the fixture constraint is removed, the heatsink deflects to the inherently bowed profile that corner loading exhibits and results in the center of the heatsink bowing up, and away from the TIM. The bowing up of the heatsink causes the central portion thereof to move away from the TIM, which has already been compressed to a fixed height before the fixture is removed and may result in separation and air entrapment between the heatsink pedestal and the TIM. History has shown air entrapment to be a cause of TIM failure.

### SUMMARY OF THE INVENTION

The shortcomings of the prior art are overcome and additional advantages are provided through the provision of an apparatus for attaching a heatsink to an electronic module mounted on a circuit card assembly. The apparatus includes a load frame and the electronic module mounted on the circuit card assembly, the load frame having a first cutout to receive the module therethrough; a load arm defined by a first end, a second end opposite the first end and an intermediate portion between the first and second ends, the first end being pivotally coupled to one end of the load frame, the second end configured to receive at least a portion of a load screw therethrough; a spring plate disposed at an opposite end of the one end of the load frame, the spring plate configured to threadedly receive the load screw, opposite ends of the spring plate being retained while an intermediate portion threadedly receiving the at least a portion of the load screw is allowed to bow upwards toward a bottom of the opposite end of the load arm; and a heatsink disposed on the module, the intermediate portion of the load arm corresponds to a center region of the module and biases the heatsink toward the module when the load screw is threadedly engaged with the spring plate. The heatsink is configured with a channel extending in a direction corresponding to the first and second ends of the load frame allowing the load arm to nest inside the channel.

In another embodiment, a method for attaching a heatsink to an electronic module mounted on a circuit card assembly is provided. The method includes: mounting a load frame and the electronic module on the circuit card assembly, the load frame having a first cutout to receive the module therethrough; pivotally coupling a first end of a load arm to one end of the load frame and pivoting a second end of the load arm opposite the first end toward an opposite end of the load frame, the load arm having an intermediate portion between the first and second ends, the second end configured to receive at least a portion of a load screw therethrough; disposing a spring plate at an opposite end of the one end of the load frame; configuring the spring plate to threadedly receive the load screw, such that opposite ends of the spring plate are retained by the load frame while an intermediate portion of the spring plate threadedly receiving the at least a portion of the load screw is allowed to bow upwards toward a bottom of the opposite end of the load arm; and disposing a heatsink on the module, the intermediate portion of the load arm corresponds to a center region of the module and biases the heatsink toward the module when the load screw is threadedly engaged with the spring plate. The heatsink is configured with a channel extending in a direction corresponding to the first and second ends of the load frame allowing the load arm to nest inside the channel.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is an exploded perspective view of an exemplary embodiment of an apparatus for mounting a heatsink with an electronic module in accordance with the present invention;

FIG. 2 is a perspective view of the heatsink disposed on the electronic module of FIG. 1 illustrating a load arm pivotally coupled at one end to the apparatus and pivoted in a raised position;

FIG. 3 is an elevation end view of the apparatus of FIG. 2 illustrating the load arm pivoted to a lowered position to receive a load screw at an opposite end of the load arm; and

FIG. 4 is an elevation end view of the apparatus of FIG. 3 illustrating the load screw extending through the opposite end of the load arm and threadedly engaged with a spring plate disposed below the opposite end of the load arm.

The detailed description explains the preferred embodiments of the invention, together with advantages and features, by way of example with reference to the drawings.

### DETAILED DESCRIPTION OF THE INVENTION

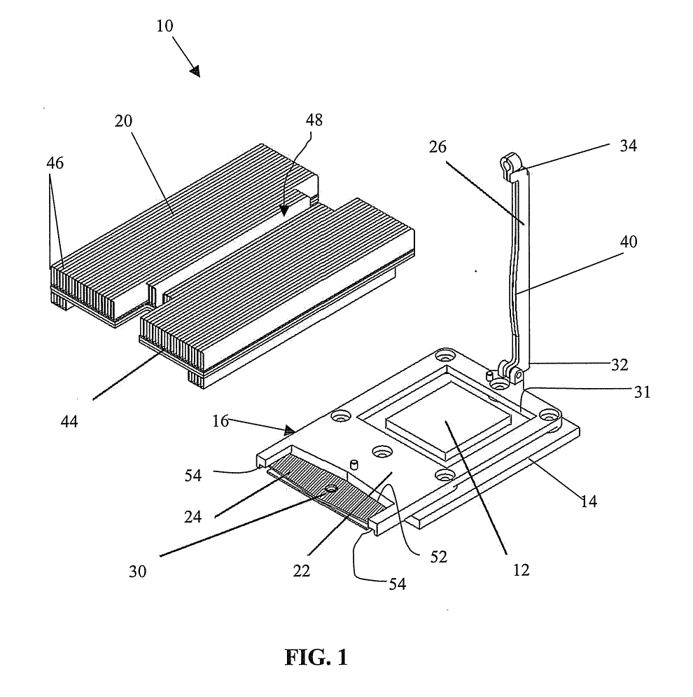

Turning now to the drawings in greater detail, it will be seen that FIG. 1 illustrates an apparatus 10 that allows very accurate heatsink load control for a low profile (e.g., blade server) application. The components of the apparatus 10 include an electronic module 12 (e.g., processor module), a circuit card assembly 14, a load frame assembly 16, and a heatsink 20.

In exemplary embodiments, the circuit card assembly 14 includes a system planar and backside stiffener (not shown) disposed under the load frame assembly 16. The system planar and backside stiffener is mostly cut away for sake of clarity in FIG. 1.

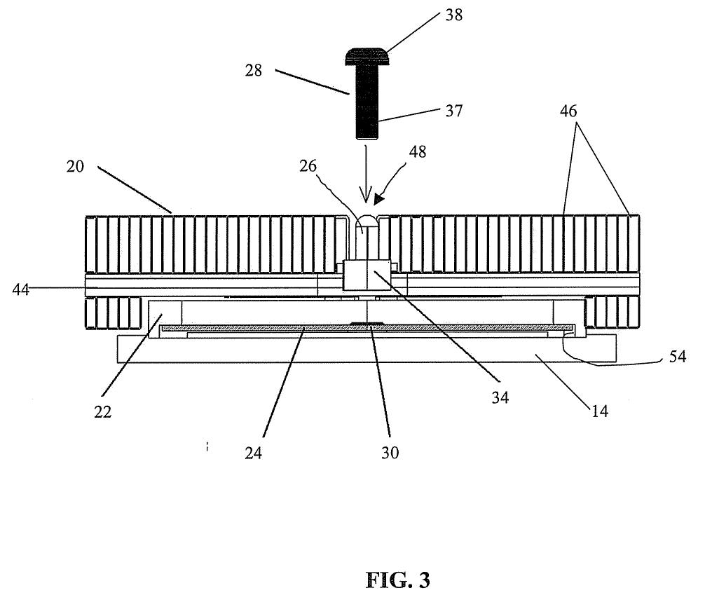

The load frame assembly 16 includes a load frame 22, a spring plate 24, a load arm 26 and a load screw 28 (FIG. 3). The spring plate 24 is configured to threadedly receive the load screw 28. In exemplary embodiments, the spring plate 24 includes a bushing 30. The load frame 22 includes a plurality of apertures (six shown) in which to mount the load frame 22 to the circuit card assembly 14. The electronic module 12 extends through a first cutout 31 in the load frame 22.

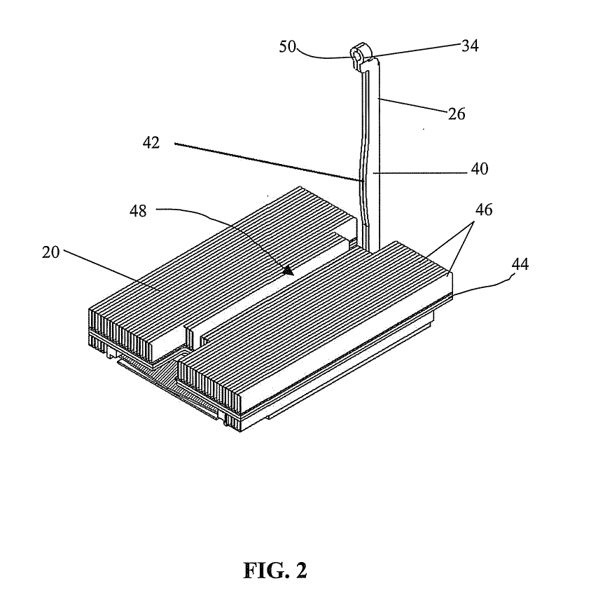

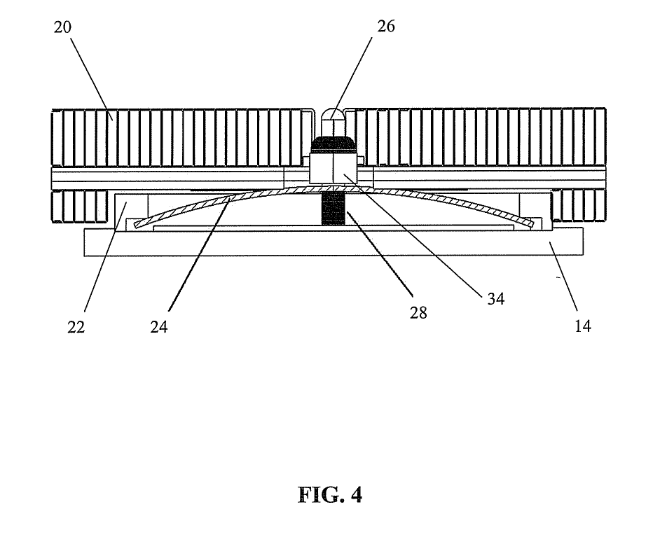

Referring to FIGS. 1 and 2, the load arm 26 is configured to be quite rigid having a first end 32 and a second end 34 opposite the first end 32. The first end 32 is pivotally coupled to the load frame 22. The load arm 26 is pinned at the first end 32 to the load frame 22 so that it may be swung open, allowing for installation and removal of the heatsink 20. The other second end 34 of the load arm 26 has a feature to accommodate the load screw 28. More specifically, the second end 34 of the load arm 26 is configured to receive at least a portion 37 of the load screw 28 therethrough while retaining a head 38 of the load screw 28 (see FIGS. 3 and 4). The load frame 22 includes an intermediate portion 40 between the first end 32 and the second end 34 of the load frame 22. The intermediate portion 40 of load arm 26 has a curved lower surface defining a load point 42 (FIG. 2). In exemplary embodiments, the load arm 26 is formed of sheet metal, but is not necessarily limited thereto.

After positioning the heatsink 20 on the module 12 and referring to FIGS. 2 and 3, the load arm 26 is lowered into position (FIG. 3). The heatsink 20 is defined by a base 44 and a plurality of fins 46 extending from the base 44. The heatsink 20 has a channel 48 extending through the center of the heatsink 20 which allows the load arm 26 to nest inside, thereby keeping the height of packaging to a minimum. The channel 48 is defined by an absence of fins 46 extending in a same direction of the channel 48 in an exemplary embodiment. The load point 42 of the load arm 26 is at the lowest point or tangent point of the curved or intermediate portion 40 of the load arm 24 in the lowered position. The load point 42 contacts the base 44 of the heatsink 20 aligned directly over the center region of the processor module 20 when the load arm 26 is in the lowered position as illustrated in FIGS. 3 and 4.

After the load arm 26 is lowered into position, the load screw 28 is passed through an aperture 50 (FIG. 2) in the second end 34 of the arm 24, and threaded into the bushing 30 disposed with the spring plate 26 bushing. In exemplary embodiments, the bushing 30 is a threaded insert that is pressed into the spring plate 26. The load frame 22 is designed such that the spring plate 24 is captured, located, and supported as part of the assembly 16. More specifically with reference to FIGS. 1 and 3, one end of the load frame 22 is configured with a second cutout 52 defined by two opposing shoulders 54. Each of the opposing shoulders 54 is configured to capture, locate and support a respective end of the spring plate 24. The spring plate 24 must be slightly deformed to be snapped into position when the load frame 22 is mounted to the circuit card assembly 14 as will be recognized by those skilled in the pertinent art. However, having the spring plate 24 captured as part of the load frame assembly 16 eliminates risk of assembly errors. For example, if the spring plate 24 is installed upside-down, the bushing 30 my pop out of the spring plate 24 under load. Therefore, it is contemplated that the spring plate 24 may be captured as part of the load frame assembly 16 before the load frame assembly is mounted to the circuit card assembly 14 in alternative exemplary embodiments.

Referring now to FIG. 4, upon tightening the load screw 28 relative to the bushing 30, the spring plate 24 is bowed upwards. Threaded engagement between the load screw 28 and bushing 30 pulls the second end 34 of the load arm 26 downward, loading the heatsink 20 and processor module 20. In this instance, there is a leverage factor, as the distance between the first end 32 and center region of the module and distance between the second end 34 and center region of the module (e.g., pin-module-screw distances) are not equal. One skilled in the art would recognize that this leverage is not necessary for the mechanism to work. For example, it may be a 1:1 ratio, or any other ratio. The loading operation is complete when the spring plate 24 and bottom of the second end 34 of load arm 26 contact each other. This point corresponds to the design load (e.g., 200 lb at the module in this application). Alternatively, a predetermined torque may be applied to the load screw 28 which will ensure that the components touch, eliminating the need to watch for contact between spring plate 24 and bottom of the second end 34 of load arm 26.

Although the exemplary heatsink loading apparatus discussed above provides proper loading of the heatsink on the module, the exemplary heatsink loading apparatus also provides the module/socket load necessary to ensure an electrical interconnection between the module and the board via the land grid array (LGA) (or hybrid LGA) connector. The center-point loading of heatsinks eliminates or minimizes the shortcomings discussed above with respect to corner loading mechanisms, and that the hardware disclosed is a novel and extremely compact application of center-point loading, designed for, but not limited to, very low-profile applications (e.g., blades). Furthermore, the heatsink loading apparatus discussed above is capable of developing a load not only sufficient to develop a good heatsink module interface, but also sufficient to engage typical LGA or hybrid LGA sockets.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. An apparatus for attaching a heatsink to an electronic module mounted on a circuit card assembly, the apparatus comprising:
a load frame and the electronic module mounted on the circuit card assembly, the load frame having a first cutout to receive the module therethrough;
a load arm defined by a first end, a second end opposite the first end and an intermediate portion between the first and second ends, the first end being pivotally coupled to one end of the load frame, the second end configured to receive at least a portion of a load screw therethrough;
a spring plate disposed at an opposite end of the one end of the load frame, the spring plate configured to threadedly receive the load screw, opposite ends of the spring plate being retained while an intermediate portion threadedly receiving the at least a portion of the load screw is allowed to bow upwards toward a bottom of the opposite end of the load arm; and
a heatsink disposed on the module, the intermediate portion of the load arm corresponds to a center region of the module and biases the heatsink toward the module when the load screw is threadedly engaged with the spring plate,
wherein the heatsink is configured with a channel extending in a direction corresponding to the first and second ends of the load frame allowing the load arm to nest inside the channel.

2. The apparatus of claim 1, wherein the intermediate portion of the load arm is the lowest point of the load arm and corresponds to a load point thereof, which in turn corresponds to the center region of the module.

3. The apparatus of claim 1, wherein the spring plate includes a threaded insert to threadedly receive the load screw.

4. The apparatus of claim 3, wherein the threaded insert is pressed into the spring plate.

5. The apparatus of claim 1, wherein the load frame is configured to capture, locate and support the spring plate.

6. The apparatus of claim 5, wherein the load frame is configured with a second cutout to capture, locate and support the spring plate.

7. The apparatus of claim 1, wherein the load screw is tightened to a predetermined torque or until the spring plate and load arm contact each other.

8. The apparatus of claim 1, wherein the circuit card assembly includes a system planar and a backside stiffener.

9. A method for attaching a heatsink to an electronic module mounted on a circuit card assembly, the method comprising:
mounting a load frame and the electronic module on the circuit card assembly, the load frame having a first cutout to receive the module therethrough;
pivotally coupling a first end of a load arm to one end of the load frame and pivoting a second end of the load arm opposite the first end toward an opposite end of the load frame, the load arm having an intermediate portion between the first and second ends, the second end configured to receive at least a portion of a load screw therethrough;
disposing a spring plate at an opposite end of the one end of the load frame;
configuring the spring plate to threadedly receive the load screw, such that opposite ends of the spring plate are retained by the load frame while an intermediate portion of the spring plate threadedly receiving the at least a portion of the load screw is allowed to bow upwards toward a bottom of the opposite end of the load arm; and
disposing a heatsink on the module, the intermediate portion of the load arm corresponds to a center region of the module and biases the heatsink toward the module when the load screw is threadedly engaged with the spring plate,
wherein the heatsink is configured with a channel extending in a direction corresponding to the first and second ends of the load frame allowing the load arm to nest inside the channel.

10. The method of claim 9, wherein the intermediate portion of the load arm corresponds to the lowest point of the load arm and corresponds to a load point thereof, which in turn corresponds to the center region of the module.

11. The method of claim 9, wherein the spring plate includes a threaded insert to threadedly receive the load screw.

12. The method of claim 11, wherein the threaded insert is pressed into the spring plate.

13. The method of claim 9, further comprising configuring the load frame to capture, locate and support the spring plate.

14. The method of claim 13, further comprising configuring the load frame having a second cutout to capture, locate and support the spring plate.

15. The method of claim 9, further comprising tightening the load screw to a predetermined torque or until the spring plate and load arm contact each other.

16. The method of claim 9, wherein the circuit card assembly includes a system planar and a backside stiffener.
